(19) United States
(12) Patent Application Publication
(10) Pub. No.: US 2022/0190578 A1
(43) Pub. Date: Jun. 16, 2022

(54) BUS BAR HEAT DISSIPATION STRUCTURE

(71) Applicant: TOYODA IRON WORKS CO., LTD., Toyota-shi, Aichi (JP)

(72) Inventors: Hideaki SAKAI, Toyota-shi (JP); Kunihiro IWATA, Toyota-shi (JP); Ken KOBAYASHI, Toyota-shi (JP)

(21) Appl. No.: 17/436,654

(22) PCT Filed: Jan. 31, 2020
(86) PCT No.: PCT/JP2020/003578

§ 371 Date: Sep. 7, 2021

(30) Foreign Application Priority Data
Mar. 13, 2019 (JP) 2019-045401

(51) Int. Cl. H02G 5/10; H02G 5/02

(52) U.S. Cl. CPC H02G 5/10; H02G 5/025

(57) ABSTRACT

A heat dissipation structure for a bus bar includes a bus bar, a covering member, which is made of plastic and covers the bus bar, and a case, which is made of metal. The covering member includes a contacting portion that contacts the case. The covering member is molded integrally with the bus bar by inserting the bus bar.

### TECHNICAL FIELD

The present disclosure relates to a heat dissipation structure for a bus bar.

### BACKGROUND ART

Patent Document 1 discloses an electrical junction box that includes a bus bar and a case to which the bus bar is fixed. In the electrical junction box disclosed in Patent Document 1, the bus bar is fixed to the case, which is made of a thermally conductive material. The heat of the bus bar is dissipated to the outside of the case via a contacting portion between the bus bar and the case.

### PRIOR ART DOCUMENT

### Patent Document

Patent Document 1: Japanese Laid-Open Patent Publication No. 2016-25673

### SUMMARY OF THE INVENTION

### Problems that the Invention is to Solve

In the electrical junction box disclosed in Patent Document 1, the bus bar and the case are formed separately and assembled together. Thus, manufacturing errors such as assembly errors may create a gap between the bus bar and the case. As a result, the contact area between the bus bar and the case may be reduced, impairing the heat transferring performance from bus bar to the case. Thus, the heat dissipation performance of the bus bar deteriorates, accordingly.

Accordingly, it is an objective of the present disclosure to provide a heat dissipation structure for a bus bar that improves heat dissipation performance.

### Means for Solving the Problems

To achieve the foregoing objective, a heat dissipation structure for a bus bar includes a bus bar, a covering member that is made of a plastic and covers the bus bar, and a case that is made of a metal. The covering member includes a contacting portion that contacts the case. The covering member is molded integrally with the bus bar by inserting the bus bar.

### BRIEF DESCRIPTION OF THE DRAWINGS

FIG. 1 is a perspective view of a heat dissipation structure for a bus bar according to a first embodiment.

FIG. 2A is a perspective view of the bus bar according to the first embodiment, as viewed from the top.

FIG. 2B is a perspective view of the bus bar according to the first embodiment, as viewed from the bottom.

FIG. 3A is a cross-sectional view taken along line 3a-3a of FIG. 1.

FIG. 3B is a cross-sectional view taken along line 3b-3b of FIG. 1.

FIG. 4 is a cross-sectional view taken along line 4-4 of FIG. 1.

FIG. 5 is a perspective view of a bus bar according to a second embodiment as viewed from the top.

FIG. 6A is a cross-sectional view taken along line 6a-6a of FIG. 5.

FIG. 6B is a cross-sectional view taken along line 6b-6b of FIG. 5.

### MODES FOR CARRYING OUT THE INVENTION

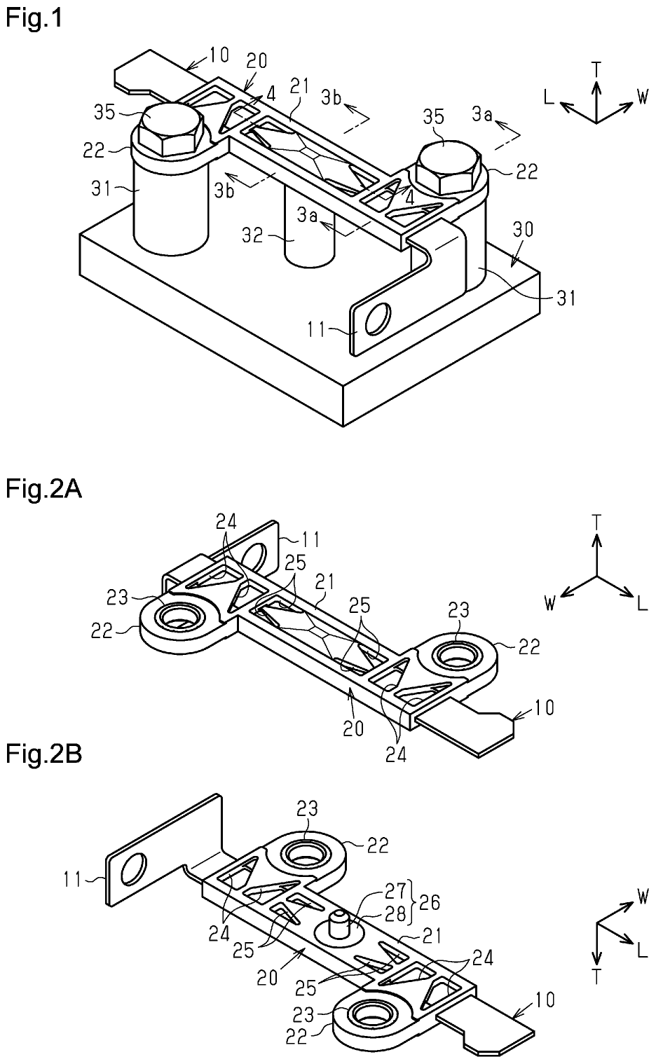

A heat dissipation structure for a bus bar according to a first embodiment will now be described with reference to FIGS. 1 to 4.

As shown in FIGS. 1, 2A, and 2B, a bus bar 10 is formed by an elongated metal plate made of metal such as copper or aluminum. The bus bar 10 includes a connection portion 11, which is formed by bending one end of the bus bar 10 and is electrically connected to another component.

As shown in FIG. 1, the bus bar 10 is attached to a case 30, which is made of metal such as aluminum. FIG. 1 shows only part of the case 30.

In the following description, the longitudinal direction of the bus bar 10 will simply be referred to as a longitudinal direction L, the width direction of the bus bar 10 will simply be referred to as a width direction W, and the thickness direction of the bus bar 10 will simply be referred to as a thickness direction T.

A covering member 20 is provided in a center portion in the longitudinal direction L of the bus bar 10 to cover the entire outer perimeter of the bus bar 10. The covering member 20 of the present embodiment includes a main body 21 and an elastic portion 28.

The main body 21 is made of a hard plastic and extends in the longitudinal direction L to cover the bus bar 10. The main body 21 is preferably made of a plastic having high thermal conductivity. Examples of such plastic include polyamide-6 (PA6) plastic, polyamide-66 (PA66) plastic, polyphenylene sulfide (PPS) plastic, and polybutylene terephthalate (PBT) plastic.

Two attachment portions 22 are respectively provided at the opposite ends in the longitudinal direction LT of the main body 21. The attachment portions 22 protrude away from each other in the width direction W.

As shown in FIGS. 2A and 2B, the main body 21 includes multiple (eight in total) lightening portions 24 at the opposite ends in the longitudinal direction L. Each lightening portion 24 has a trapezoidal shape in a plan view and exposes part of the opposite surfaces in the thickness direction T of the bus bar 10.

Also, the main body 21 includes multiple (eight in total) lightening portions 25 at positions inward of the lightening portions 24 in the longitudinal direction L. Each lightening portion 25 has the shape of a right triangle in a plan view and exposes part of the opposite surfaces in the thickness direction T of the bus bar 10.

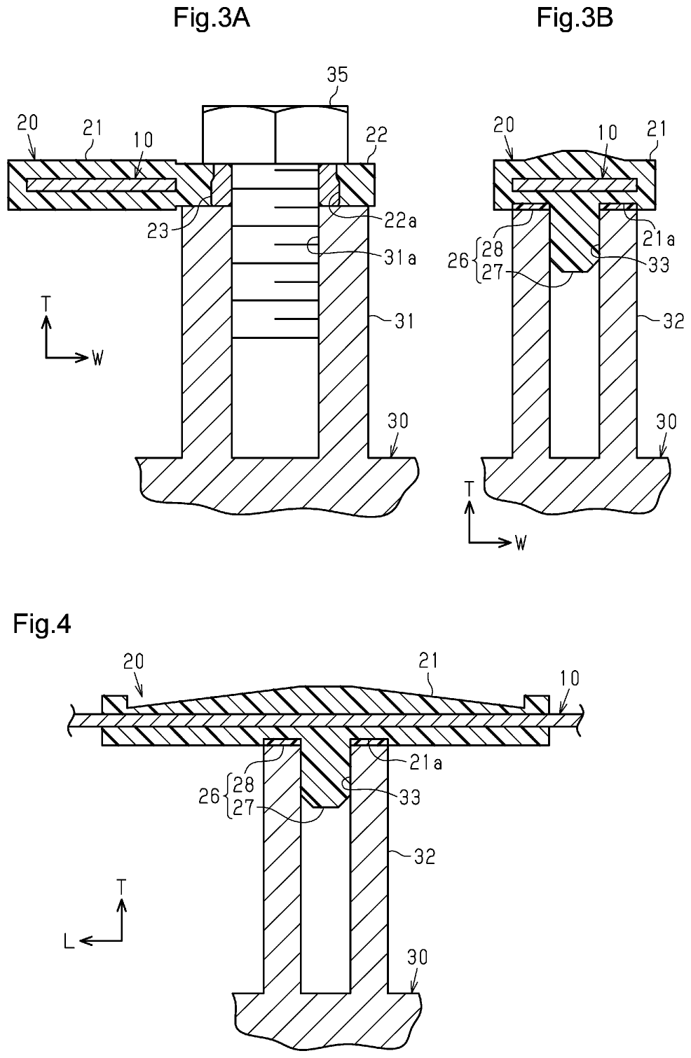

As shown in FIGS. 2A, 2B, and 3A, a cylindrical collar 23 is fixed to each attachment portion 22. The cylindrical collar 23 is made of metal such as aluminum.

As shown in FIG. 3A, the attachment portion 22 includes a hole 22a, which extends through the attachment portion 22 in the thickness direction T. The collar 23 is fixed inside the hole 22a.

As shown in FIGS. 2B, 3B, and 4, the main body 21 includes a columnar protrusion 27 on the bottom surface, which is the surface facing the case 30. The protrusion 27 protrudes toward the case 30.

As shown in FIGS. 3B and 4, the main body 21 includes annular recess 21a at the outer circumference of the protrusion 27. The elastic portion 28 is fitted in the recess 21a. The elastic portion 28 is shaped as a disc with a center hole and is made of a plastic softer than that of the main body 21. The elastic portion 28 is flush with the bottom surface of the main body 21. The plastic of the elastic portion 28 is preferably an elastomer having a high heat resistance, such as silicone.

The main body 21 is molded integrally with the bus bar 10 and the collar 23 by inserting the bus bar 10 and the collar 23 into a molding die (not shown) and injecting molten plastic into the cavity (not shown) in the molding die. At this time, the lightening portions 24, 25 are formed by clamps (not shown) holding the opposite surfaces of the bus bar 10 in the thickness direction T.

Also, the elastic portion 28 is molded integrally with the main body 21 by inserting the bus bar 10 and the main body 21, which is molded integrally with the collar 23, into a molding die (not shown) and injecting molten plastic into the cavity (not shown) in the molding die.

As shown in FIGS. 3B and 4, a second support portion 32 protrudes from the case 30. The second support portion 32 has a fitting recess 33 opening in the top surface. The protrusion 27 is fitted into the fitting recess 33. This positions the bus bar 10 in relation to the case 30.

As shown in FIG. 3A, a bolt 35 is inserted into the collar 23 of each attachment portion 22. First support portions 31 protrude from the case 30. Each bolt 35 is threaded into an internal thread hole 31a, which opens in the top surface of the corresponding first support portion 31. This fixes the bus bar 10 to the case 30 as shown in FIG. 1. The elastic portion 28 is held between the main body 21 and the end face of the second support portion 32.

In the present embodiment, the protrusion 27 of the main body 21 and the elastic portion 28 form a contacting portion 26, which contacts the case 30.

As shown in FIGS. 3B and 4, the top surface of the main body 21 of the covering member 20 is inclined such that the distance from the bus bar 10 increases toward the contacting portion 26 both in the longitudinal direction L and the width direction W. Accordingly, the thickness of the covering member 20 increases toward the contacting portion 26 both in the longitudinal direction L and the width direction W. That is, the thickness of the covering member 20 at the contacting portion 26 is greater than that in the area around the contacting portion 26.

The present embodiment has the following advantages.

(1) The heat dissipation structure for the bus bar 10 includes the bus bar 10, the covering member 20, which is made of plastic and covers the bus bar 10, and the case 30, which is made of metal. The covering member 20 includes the contacting portion 26, which contacts the case 30. The covering member 20 is molded integrally with the bus bar 10 by inserting the bus bar 10.

With this configuration, since the covering member 20, which is made of plastic, is molded integrally with the bus bar 10 by inserting the bus bar 10, almost no gap exists between the bus bar 10 and the covering member 20. The heat of the bus bar 10 is easily transferred to the covering member 20 directly. The thus transferred heat is transferred to the case 30 via the contacting portion 26 of the covering member 20. This improves the heat dissipation performance of the bus bar 10.

(2) The thickness of the covering member 20 at the contacting portion 26 is greater than that in the area around the contacting portion 26. Also, the thickness of the covering member 20 increases toward the contacting portion 26.

With this configuration, the heat transferred to the covering member 20 from the bus bar 10 is transferred from the area around the contacting portion 26 toward the contacting portion 26, which is capable of storing a large amount of heat due to its relatively large thickness. This allows a large amount of heat to be transferred to the case 30 via the contacting portion 26.

(3) The contacting portion 26 includes the protrusion 27, which protrudes toward the case 30. The case 30 includes the fitting recess 33, which receives the protrusion 27.

This configuration positions the covering member 20 and the bus bar 10 in relation to the case 30 by fitting the protrusion 27 of the contacting portion 26 into the fitting recess 33 of the case 30.

The addition of the protrusion 27 and the fitting recess 33 increases the contact area between the contacting portion 26 and the case 30. This further improves the heat dissipation performance of the bus bar 10.

(4) The covering member 20 includes the main body 21, which covers the bus bar 10, and the elastic portion 28, which is made of plastic softer than that of the main body 21 and is disposed between the main body 21 and the case 30.

With this configuration, the bus bar 10 and the covering member 20 can be attached to the case 30 with the elastic portion 28 elastically deformed between the covering member 20 and the case 30. This prevents a gap from being created between the covering member 20 and the case 30. Thus, the heat of the covering member 20 is transferred to the case 30 effectively.

### Second Embodiment

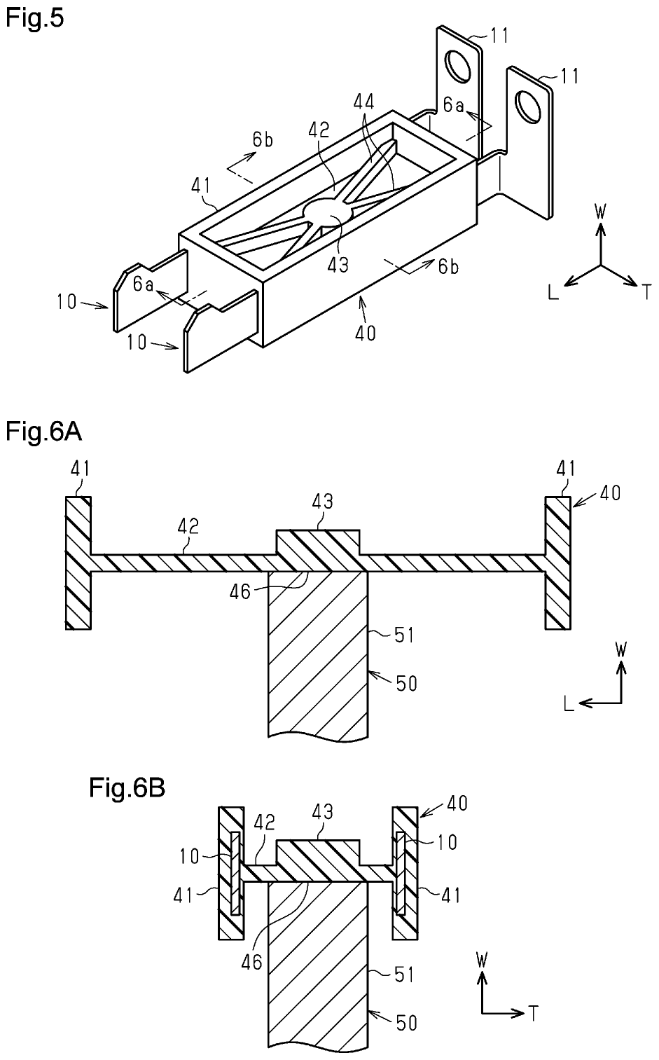

A second embodiment will now be described with reference to FIGS. 5 and 6. Differences from the first embodiment will mainly be discussed.

As shown in FIG. 5, the present embodiment includes two bus bars 10 arranged parallel with each other. Specifically, the bus bars 10 are arranged to face each other in the thickness direction T thereof.

As shown in FIGS. 5, 6A, and 6B, a covering member 40 is molded integrally with the bus bars 10.

The covering member 40 includes a rectangular tube-shaped frame portion 41 and a plate portion 42 disposed inside the frame portion 41. The frame portion 41 includes two long-side sections, which respectively cover the entire outer perimeters of the bus bars 10. The plate portion 42 is located at the center in the width direction W of the frame portion 41 and is coupled to the entire inner surface of the frame portion 41.

As shown in FIGS. 6A and 6B, the plate portion 42 includes a contacting portion 46 at the center on the bottom surface. The contacting portion 46 contacts the top surface of a support portion 51, which protrudes from a case 50. That is, the contacting portion 46 is disposed between the adjacent bus bars 10. Like the case 30 of the first embodiment, the case 50 is made of metal such as aluminum.

The plate portion 42 includes a columnar protrusion 43 in the section of the top surface that corresponds to the contacting portion 46. That is, the thickness of the covering member 40 at the contacting portion 46 is greater than that in the area around the contacting portion 46.

As shown in FIG. 5, two ribs 44 are disposed on the top surface of the plate portion 42. The ribs 44 respectively extend along the diagonal lines of the frame portion 41.

The covering member 40 of the present embodiment lacks a structure equivalent to the elastic portion 28 described in the first embodiment.

The present embodiment has the following advantages.

(5) The covering member 40 is molded integrally with the bus bars 10.

With this configuration, the two bus bars 10 are integrated together by the covering member 40. This improves the heat dissipation performance of the bus bars 10 and facilitates the assembly to the case 50.

(6) The contacting portion 46 is disposed between the adjacent bus bars 10.

With this configuration, since the contacting portion 46 is disposed between the bus bars 10, which are adjacent to each other, the section of the case 50 that contacts the contacting portion 46 is concentrated. Thus, the structures of the covering member 40 and the case 50 are simplified.

### Modifications

The above-described embodiments may be modified as follows. The above-described embodiments and the following modifications can be combined as long as the combined modifications remain technically consistent with each other.

The number and the shape of the lightening portions 24 may be changed. The lightening portions 24 may be omitted.

The number and the shape of the lightening portions 25 may be changed. The lightening portions 25 may be omitted.

The second embodiment may include two contacting portions 46 respectively corresponding to the two bus bars 10.

In the second embodiment, the covering member 40 may be molded integrally with three or more bus bars 10.

The elastic portion 28 of the first embodiment may be omitted.

A component equivalent to the elastic portion 28 described in the first embodiment may be bonded to the bottom surface of the plate portion 42. That is, an elastic portion does not necessarily need to be molded integrally with the main body of a covering member.

The protrusion 27 of the first embodiment may be omitted. In this case, it is preferable to omit the fitting recess 33 of the case 30.

In the first embodiment, the main body 21 of the covering member 20 may have a constant thickness. In the second embodiment, the protrusion 43 and/or the ribs 44 may be omitted from the plate portion 42 of the covering member 40.

1. A heat dissipation structure for a bus bar, comprising:
a bus bar;
a covering member that is made of a plastic and covers the bus bar; and
a case that is made of a metal,
wherein the covering member includes a contacting portion that contacts the case, the covering member being molded integrally with the bus bar by inserting the bus bar.

2. The heat dissipation structure for a bus bar according to claim 1, wherein a thickness of the covering member at the contacting portion is greater than that in an area around the contacting portion.

3. The heat dissipation structure for a bus bar according to claim 2, wherein the thickness of the covering member increases toward the contacting portion.

4. The heat dissipation structure for a bus bar according to claim 1, wherein
the contacting portion includes a protrusion that protrudes toward the case, and
the case includes a fitting recess that receives the protrusion.

5. The heat dissipation structure for a bus bar according to claim 1, wherein the covering member includes:
a main body that covers the bus bar; and
an elastic portion that is made of a plastic softer than that of the main body and disposed between the main body and the case.

6. The heat dissipation structure for a bus bar according to claim 1, wherein
the bus bar is one of a plurality of bus bars, and
the covering member is molded integrally with the plurality of bus bars.

7. The heat dissipation structure for a bus bar according to claim 6, wherein the contact portion is disposed between adjacent two bus bars of the plurality of bus bars.
